(19) United States
(12) Patent Application Publication
(10) Pub. No.: US 2007/0238283 A1
(43) Pub. Date: Oct. 11, 2007

(54) NOVEL UNDER-BUMP METALLIZATION FOR BOND PAD SOLDERING

(75) Inventors: Chih-Chiang Chen, Hsinchu (TW); Chender Huang, Hsin-Chu (TW); Pei-Haw Tsao, Tai-chung (TW); Chung Yu Wang, Hsin Chu (TW); Wen Sze Huang, Pingjhen City (TW)

Correspondence Address: DUANE MORRIS LLP;IP DEPARTMENT (TSMC), 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 11/278,684

(22) Filed: Apr. 5, 2006

(51) Int. Cl. H01L 21/44

(52) U.S. Cl. 438/613; 257/E23.021

(57) ABSTRACT

An under bump metallurgy (UBM) structure formed over a bond pad and for use in conjunction with a solder ball, provides an upper copper layer over a subjacent composite film that includes a nickel film over a further copper film over a titanium film. One or more reflow operations are used to form a molten solder ball and conditions are selected to ensure that all of the copper from the upper copper layer is dissolved within the molten solder. For SnAg leadfree solder, this leads to the formation of SnAgCu-like leadfree solder. The resulting interface between the solder ball and the nickel layer includes regularly spaced Cu₆Sn₅ nodules as intermetallics but is free of Ni₃Sn₄ which can spall into the molten solder causing reliability problems.

### FIELD OF THE INVENTION

The invention relates to semiconductor chip interconnection technology in general, and in particular, the invention is directed to a metallization scheme used in conjunction with solder bumps for connecting semiconductor chips to further components.

### BACKGROUND

Virtually all electronic devices and equipment include at least one semiconductor device formed on a semiconductor chip. Many electronic devices, computers, and other electrical systems include countless numbers of such semiconductor chips. Each semiconductor chip must be physically and electrically coupled to a package and/or other components within the electronic device or system. Various techniques are used to physically and electrically couple a semiconductor chip within a package and/or directly to other components.

Standard assembly techniques for coupling a semiconductor chip to a package which is then coupled to other components, include forming bond pads on the semiconductor chip and then forming solder bumps on the bond pads. Once formed, the solder bumps are then reflowed and connected to an external component such as a package substrate or another component. In today's lead-free manufacturing environment, tin-silver SnAg solder bumps are favored. Conventional UBM (under bump metallurgy, or, alternatively, under bump metallization) structures used in conjunction with the SnAg solder bump include a Ti/Cu/Ni structure, i.e. a Ni layer formed over a Cu layer formed over a Ti layer formed over the bond pad formed on the semiconductor chip. For SnAg lead-free solder bumps, however, the Ti/Cu/Ni UBM structure includes shortcomings such as reliability concerns. The reliability concerns are thought to be attributable to the morphology of the structure. When the SnAg solder formed on the Ni layer is reflowed, an intermetallic morphology is formed that undesirably includes nodules and chunks of Ni₃Sn₄ and these nodules and chunks spall off into the solder creating reliability problems.

It would be therefore desirable to produce a lead-free SnAg solder bump without the aforementioned shortcomings.

### SUMMARY OF THE INVENTION

To address these and other needs, and in view of its purposes, the present invention provides an under-bump metallization scheme for bond pad soldering. According to one aspect, a method for forming a solder bump on a bond pad is provided. The method includes forming a first copper layer over a titanium layer over a bond pad formed on a semiconductor chip, forming a Ni layer over the first copper layer over the bond pad, forming a further copper layer over the Ni layer over the bond pad, and forming a lead-free Sn—Ag solder over the further copper layer. The structure is then reflowed using sufficient heating conditions such that all copper from the further copper layer is dissolved within the Sn—Ag solder.

According to another aspect, a method for forming a solder bump on a bond pad is provided. The method includes forming a first copper layer over a titanium layer over a bond pad formed on a semiconductor chip, forming a Ni layer over the first copper layer over the bond pad, forming a further copper layer over the Ni layer over the bond pad, and forming a lead-free Sn—Ag solder over the further copper layer. The structure is then reflowed a plurality of times before the solder bump is joined to a further component.

According to yet another aspect, provided is an interconnection structure for a semiconductor device. The interconnect structure comprises a bond pad formed on a semiconductor chip, an Ni layer disposed over a Cu layer disposed over a Ti layer disposed over the bond pad, and a generally round lead-free Sn—Ag solder ball disposed over the bond pad and contacting an upper surface of the Ni layer. The Sn—Ag solder includes an interface between the Sn—Ag solder and the Ni layer that is substantially free of Ni₃S₄ and includes at least nodules of Cu₆Sn₅ as an intermetallic.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity as necessary. Like numerals denote like features throughout the specification and drawing. The drawing includes the following figures.

FIGS. 1-6 are cross-sectional views showing a sequence of operations used to form a solder connection over a bond pad according to the invention.

### DETAILED DESCRIPTION

The invention provides for forming a new UBM (under bump metallurgy) structure that includes a top layer of copper which is consumed within the solder formed over the copper, during reflow of the solder. In one embodiment, the copper is consumed within SnAg leadfree solder and the reflow leads to the formation of SnAgCu-like leadfree solder The intermetallic formed at the interface of the solder ball and the uppermost UBM layer may advantageously include Cu₆Sn₅ nodules and be substantially free of Ni₃Sn₄.

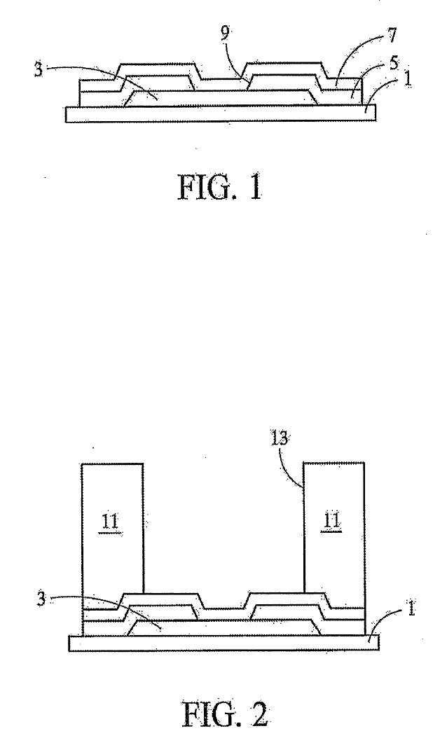

FIG. 1 is a cross-sectional view showing bond pad 3 formed over substrate 1. Substrate 1 may be a semiconductor chip and may represent various types of semiconductor integrated circuits and other devices that perform various functions. Dielectric 5 is formed over substrate 1 including portions of bond pad 3 but includes opening 9 exposing portions of bond pad 3. The UBM includes lower conductive layer 7 which may be formed of a single material or a plurality of materials such as a composite layer of two films. In one exemplary embodiment, lower conductive layer 7 may be formed of a copper layer formed over a titanium layer. In one exemplary embodiment, each of the titanium layer and the copper layer may be formed by a blanket sputtering operation and the films may initially extend over substrate 1 in regions besides over bond pad 3. Plating may alternatively be used to form the film(s) that make up lower conductive layer 7.

FIG. 2 shows the structure of FIG. 1 after patterning film 11 has been formed over substrate 1. Patterning film 11 includes opening 13 over bond pad 3. Patterning film 11 may be dry film photoresist in one exemplary embodiment and may be patterned using conventional photolithography techniques. In other exemplary embodiments, patterning film 11 may be a spin-on photoresist and conventional techniques may be used to form and pattern the spin-on photoresist.

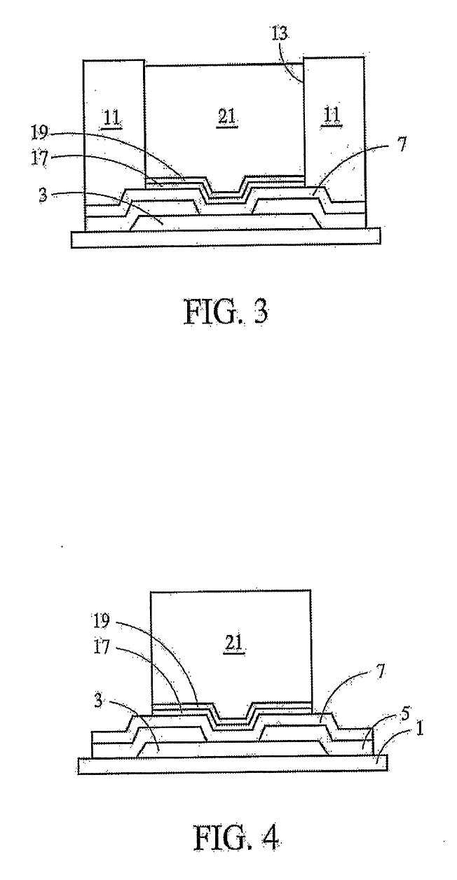

Now turning to FIG. 3, films 17 and 19 are sequentially formed over lower conductive layer 7. Film 17 may be Ni which may be advantageously formed by electroplating. Film 19, formed over film 17, may also be formed by electroplating and may advantageously be formed of copper. Other plating techniques such as electro-less plating may be used in other exemplary embodiments to form films 17 and 19. In still other exemplary embodiments, either or both of films 17 and 19 may be formed by sputtering. Solder material 21 is then formed within opening 13 and directly on film 19. Conventional methods such as plating or printing may be used for forming solder material 21 within opening 13. Solder material 21 may be a lead-free solder material and may be formed of Sn—Ag in various compositions. In one embodiment, the solder material may include a Sn-3.5Ag composition but other material compositions may be used in other embodiments.

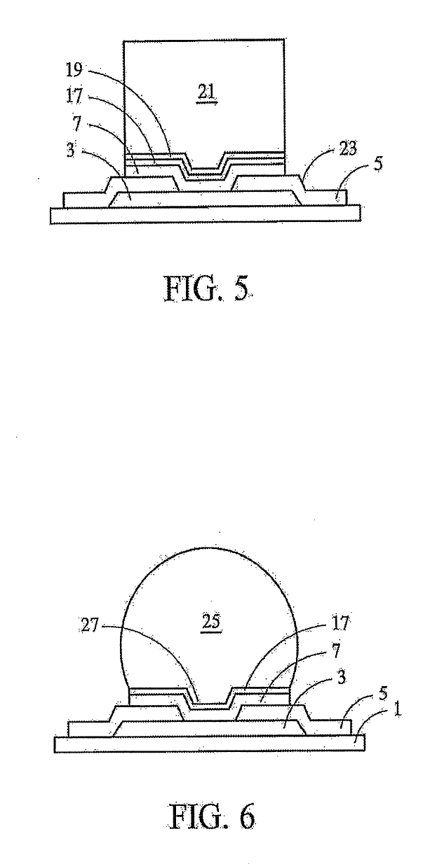

FIG. 4 shows the structure of FIG. 3 after patterning film 11 and portions of films 17 and 19 have been sequentially removed and FIG. 5 shows the structure after lower conductive film 7 has then been removed. Conventional techniques may be used to remove patterning film 11. Conventional etching techniques such as an HF etching solution may be used to sequentially remove film 19, film 17 and lower conductive film 7, exposing surfaces 23 of dielectric 5 in regions not masked by solder material 21.

The structure shown in FIG. 5 will then undergo thermal operations to melt solder material 21 and produce a generally round solder ball coupled to bond pad 3 and which is attachable to further components in subsequent assembly operations.

One or more reflow operations are used to assure that virtually all of the copper from film 19 is dissolved into the solder material as solder ball 25 forms from solder material 21 as shown in FIG. 6. Note that film 19 is absent from FIG. 6 as all the copper from film 19 has been dissolved in solder ball 25. Solder ball 25 is generally round, i.e. spherical, and has not yet been connected to a further component such as a package or another electronic or semiconductor structure.

In one embodiment, two or more reflow operations may be used to reflow the solder illustrated as material 21 in FIG. 5, to form solder ball 25 as shown in FIG. 6. Each reflow operation may include a ramp-up and ramp-down portion and a portion at a maximum temperature and each reflow operation may take place for a total of 4-10 minutes, although different times may be used in other exemplary embodiments. According to one exemplary embodiment, a maximum temperature within the range of 200-260° C. may be achieved for a time of about 1-2 minutes, but other maximum temperatures may be achieved for other times in other exemplary embodiments. The reflow operation or plurality of operations are chosen to ensure that all of film 19, which may be copper, is dissolved within the solder to form solder ball 25. Intermetallics are formed at interface 27 between solder ball 25 and film 17, which may be Ni. The intermetallics may include regularly spaced nodules of Cu₆Sn₅ and the interface will be substantially free of Ni₃Sn₄ for various Sn—Ag solder materials used, such as Sn-3.5Ag solder. Spalling of the interfacial intermetallics into the molten solder, such as occurs with the formation of Ni₃Sn₄ as an intermetallic, is prevented due to the presence of copper in the solder during reflow. The copper inhibits growth and spalling of the intermetallic because it saturates the solder. After the solder ball 25 is formed as shown in FIG. 6, substrate 1 may be joined to a package or another component using any of various techniques for electrically and physically coupling a solder ball to the package or further component. The lead-free Sn—Ag solder structure joined to bond pad 3 provides improved reliability due to the presence of Cu₆Sn₅ and absence of undesirable intermetallics that may spall off into the solder during the reflow processes that may be used to join the semiconductor chip, i.e., substrate 1, to a package or other component.

The preceding merely illustrates the principles of the invention. It will thus be appreciated that those skilled in the art will be able to devise various arrangements which, although not explicitly described or shown herein, embody the principles of the invention and are included within its spirit and scope. For example, the exemplary process sequence illustrated in FIGS. 1-6 is known as a print and bump process but the methods of the present invention are not limited to such a process sequence. Rather, the disclosed UBM structure and solder reflow process which reflows the solder using conditions sufficient to consume all of the copper from the upper copper layer of the UBM structure, may be used in conjunction with different process sequences for forming the films over a bond pad and disposing a solder paste over the UBM structure.

All examples and conditional language recited herein are principally intended expressly to be only for pedagogical purposes and to aid in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the structure be constructed or operated in a particular orientation.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A method for forming a solder bump on a bond pad, comprising:
forming a Ni layer over a bond pad formed on a semiconductor chip;
forming a copper layer over said Ni layer over said bond pad;
forming an Sn—Ag lead-free solder over said copper layer; and
reflowing using sufficient heating conditions such that substantially all copper from said copper layer is dissolved within said Sn—Ag lead-free solder.

2. The method as in claim 1, further comprising forming a subjacent copper layer over a titanium layer formed over said bond pad and wherein said forming a Ni layer comprises forming said Ni layer over said subjacent copper layer.

3. The method as in claim 2 wherein said forming a subjacent copper layer over a titanium layer over a bond pad comprises sputtering said titanium layer then sputtering said subjacent copper layer.

4. The method as in claim 2, wherein
said forming a subjacent copper layer over a titanium layer over a bond pad further comprises forming said subjacent copper layer and said titanium layer in further regions besides over said bond pad;
said forming a Ni layer over said subjacent copper layer comprises first forming a pattern with a dry mask or photoresist to form an opening over said bond pad then depositing said Ni layer over said subjacent copper layer in said opening;
said forming a copper layer comprises depositing said copper layer over said Ni layer within said opening; and
said forming an Sn—Ag lead-free solder comprises substantially filling said opening with said Sn—Ag lead-free solder,
and further comprising removing said dry mask or photoresist prior to said reflowing.

5. The method as in claim 1, wherein said reflowing comprises heating to a temperature within a range of 200-260° C. for 1-2 minutes at least one time.

6. The method as in claim 5, wherein said reflowing further includes a ramp-up time and a ramp-down time and takes place for a time of 4-10 minutes.

7. The method as in claim 1, wherein said Sn—Ag lead-free solder comprises Sn-3.5Ag.

8. The method as in claim 7, wherein an intermetallic region formed at an interface between said Ni layer and said Sn—Ag lead-free solder is free of Ni₃Sn₄.

9. The method as in claim 7, wherein an intermetallic region formed at an interface between said Ni layer and said Sn—Ag lead-free solder includes Cu₆Sn₅ nodules.

10. The method as in claim 1, wherein said reflowing comprises a plurality of separate reflowing operations.

11. A method for forming a solder bump on a bond pad, comprising:
forming a first copper layer over a titanium layer over a bond pad formed on a semiconductor chip;
forming a Ni layer over said first copper layer over said bond pad;
forming a second copper layer over said Ni layer over said bond pad;
forming an Sn—Ag lead-free solder over said second copper layer; and
reflowing a plurality of times before joining said Sn—Ag lead-free solder to a further component.

12. The method as in claim 11, wherein
said forming a first copper layer over a titanium layer over a bond pad further comprises forming said first copper layer and said titanium layer in further regions besides over said bond pad;
said forming a Ni layer over said first copper layer over said bond pad comprises first forming a pattern with a dry mask or photoresist to form an opening over said bond pad then depositing said Ni layer over said first copper layer in said opening;
said forming a second copper layer comprises depositing said second copper layer over said Ni layer within said opening; and
said forming an Sn—Ag lead-free solder comprises substantially filling said opening with said Sn—Ag lead-free solder,
and further comprising removing said dry mask or photoresist prior to said reflowing.

13. The method as in claim 11, wherein substantially all copper of said second copper layer becomes dissolved in said Sn—Ag lead-free solder during said reflowing.

14. The method as in claim 11, wherein each said reflowing includes a ramp-up portion and a ramp-down portion and takes place for a time between 4 and 10 minutes and comprises heating to a temperature within a range of 200-260° C. for 1-2 minutes.

15. The method as in claim 11, wherein said Sn—Ag lead-free solder comprises Sn-3.5Ag and an intermetallic formed at an interface between said Ni layer and said Sn—Ag solder is substantially free of Ni₃Sn₄.

16. The method as in claim 15, wherein said interface includes Cu₆Sn₅ nodules.

17. An interconnection structure for a semiconductor device, said interconnect structure comprising:
a bond pad formed on a semiconductor chip;
an Ni layer disposed over a Cu layer disposed over a Ti layer disposed over said bond pad; and
a generally spherical Sn—Ag lead-free solder ball disposed over said bond pad and contacting an upper surface of said Ni layer;
wherein an intermetallic formed at an interface between said Sn—Ag solder and said Ni layer includes nodules of Cu₆Sn₅ and said interface is substantially free of Ni₃Sn₄.

18. The interconnection structure as in claim 17, wherein said Sn—Ag lead-free solder comprises Sn-3.5Ag.

19. The interconnection structure as in claim 17, wherein said Ni layer is disposed directly on said Cu layer which is disposed directly on said Ti layer which is disposed directly on said bond pad.

20. The interconnection structure as in claim 17, wherein said nodules of Cu₆Sn₅ are regularly spaced.
